(19) United States
(12) Patent Application Publication
(10) Pub. No.: US 2002/0014647 A1
(43) Pub. Date: Feb. 7, 2002

(54) Trench capacitor with isolation collar and corresponding method of production

(75) Inventors: Harald Seidl, Dresden (DE); Martin Gutsche, Dorfen (DE)

Correspondence Address: GREENBLUM & BERNSTEIN, P.L.C., 1941 ROLAND CLARKE PLACE, RESTON, VA, 20191, US

(73) Assignee: INFINEON TECHNOLOGIES AG, Munchen (DE)

(21) Appl. No.: 09/899,189

(22) Filed: Jul. 6, 2001

(30) Foreign Application Priority Data
Jul. 7, 2000 (DE) 100 34 003.2

(51) Int. Cl. H01L 27/108; H01L 29/76; H01L 29/94; H01L 31/119

(52) U.S. Cl. 257/301

(57) ABSTRACT

The present invention provides a trench capacitor, in particular for use in a semiconductor memory cell, with a trench (2), which is formed in a semiconductor substrate (1); a first and second conducting capacitor plate (60, 80; 60, 100; 100″, 100′″), located in the trench (2); a dielectric layer (70), located between the first and second capacitor plates (60, 80; 60, 100; 100″, 100′″), as the capacitor dielectric; an isolation collar (5″) in the upper region of the trench (2); and an optional conducting filling material (80, 80′), filled into the trench (2). The dielectric layer (70) has been applied by an ALD or ALCVD method or a CVD method. The invention likewise provides a corresponding method of production.

The present invention relates to a trench capacitor, in particular for use in a semiconductor memory cell, with a trench which is formed in a semiconductor substrate; a first and second conducting capacitor plate, located in the trench; a dielectric layer, located between the first and second capacitor plates, as the capacitor dielectric; an isolation collar in the upper region of the trench; and a conducting filling material, filled into the trench, and to a corresponding method of production.

Although it can be applied to any desired trench capacitors, the present invention and the problems on which it is based are explained below with reference to a trench capacitor used in a DRAM memory cell. Such memory cells are used in integrated circuits (ICs), such as for example random-access memories (RAMs), dynamic RAMs (DRAMs), synchronous DRAMs (SDRAMs), static RAMs (SRAMs) and read-only memories (ROMs). Other integrated circuits contain logic devices, such as for example programmable logic arrays (PLAs), application-specific ICs (ASICs), mixing logic/memory ICs (embedded DRAMs) or other circuit devices. Usually, a multiplicity of ICs are produced in parallel on a semiconductor substrate, such as for example a silicon wafer. After processing, the wafer is divided up, in order to separate the ICs into a multiplicity of individual chips. The chips are then packaged into end products, for example for use in consumer products, such as for example computer systems, cellular phones, personal digital assistants (PDAs) and other products. For purposes of discussion, the invention is described with regard to the formation of an individual memory cell.

Integrated circuits (ICs) or chips use capacitors for the purpose of storing charges. An example of an IC which uses capacitors for storing charges is a memory IC, such as for example a chip for a dynamic random-access memory (DRAM). The charge state (“0” or “1”) in the capacitor in this case represents a data bit.

A DRAM chip contains a matrix of memory cells, which are connected up in the form of rows and columns. The row connections are usually referred to as word lines and the column connections as bit lines. The reading of data from the memory cells or the writing of data to the memory cells is realized by activating suitable word lines and bit lines.

A DRAM memory cell usually contains a transistor connected to a capacitor. The transistor contains two diffusion regions separated by a channel, above which a gate is arranged. Depending on the direction of the current flow, one diffusion region is referred to as the drain and the other as the source. The designations “drain” and “source” are used interchangeably here with regard to the diffusion regions. The gates are connected to a word line, and one of the diffusion regions is connected to a bit line. The other diffusion region is connected to the capacitor. The application of a suitable voltage to the gate switches the transistor on and enables a current flow between the diffusion regions through the channel in order in this way to form a connection between the capacitor and the bit line. The switching-off of the transistor disconnects this connection by interrupting the current flow through the channel.

The charge stored in the capacitor decreases with time on account of an inherent leakage current. Before the charge has decreased to an indefinite level (below a threshold value), the storage capacitor must be refreshed.

Ongoing endeavors to reduce the size of storage devices are encouraging the design of DRAMs with a greater density and a smaller characteristic size, i.e. a smaller memory cell area. To produce memory cells which occupy a smaller surface region, smaller components, for example capacitors, are used. However, the use of smaller capacitors results in a reduced storage capacitance, which in turn can adversely affect the functionality and usability of the storage device. For example, sense amplifiers require a sufficient signal level for reliable reading of the information in the memory cells. The ratio of the storage capacitance to the bit line capacitance is critical in determining the signal level. If the storage capacitance becomes too small, this ratio may be too small to generate a sufficient signal. Likewise, a smaller storage capacitance requires a higher refresh frequency.

One type of capacitor usually used in DRAMs is a trench capacitor. A trench capacitor has a three-dimensional structure formed in the silicon substrate. An increase in the volume or the capacitance of the trench capacitor can be achieved by etching more deeply into the substrate. In this case, the increase in the capacitance of the trench capacitor does not have the effect of enlarging the surface area occupied by the memory cell.

A customary trench capacitor contains a trench etched into the substrate. This trench is typically filled with p+- or n+-doped polysilicon, which serves as one capacitor electrode (also referred to as the storage capacitor). The second capacitor electrode is the substrate or a “buried plate”. A capacitor dielectric containing nitride, for example, is usually used to isolate the two capacitor electrodes.

A dielectric collar (preferably an oxide region) is produced in the upper region of the trench in order to prevent a leakage current or to isolate the upper part of the capacitor.

The capacitor dielectric in the upper region of the trench, where the collar is to be formed, is usually removed before said collar is formed, since this upper part of the capacitor dielectric is a hindrance to subsequent process steps.

In order to increase the storage density further for future generations of memory technology, the pattern size is reduced from generation to generation. The increasingly diminishing capacitor area and the associated diminishing capacitor capacitance leads to problems. It is therefore an important task to keep the capacitor capacitance at least constant in spite of a smaller pattern size. One way in which this can be achieved is by increasing the density of the charge per unit area of the storage capacitor.

Until now, this problem has been solved on the one hand by increasing the available capacitor area for a given pattern size, for example by widening the trench (“wet bottle”) beneath the collar or by roughening the surface in the trench. On the other hand, the density of the charge per unit area has previously been increased by reducing the thickness of the dielectric. In this respect, until now various combinations of SiO₂ (silicon dioxide) and Si₃N₄ (silicon nitride) in combination with doped silicon electrodes have been used exclusively as dielectrics for trench capacitors. A further reduction in the thickness of these materials is not possible on account of the resultant high leakage currents.

It is therefore the object of the present invention to provide an improved trench capacitor with an isolation collar which has an increased density of the charge per unit area and can be produced without the risk of increased leakage currents.

This object is achieved according to the invention by the trench capacitor specified in claims 1, 3 and 5, with an isolation collar. Furthermore, this object is achieved by the method specified in claim 14.

Preferred developments are the subject of the respective subclaims.

The procedure according to the invention as claimed in claim 1 or 14 has the advantage over the known approaches to a solution that the density of the charge per unit area can be increased by the use of special dielectrics and/or electrodes in the trench capacitor with higher dielectric constants in comparison with the dielectrics previously used, without at the same time increasing the leakage currents.

Among the methods which can be used without any problem for depositing special dielectrics with very good edge coverage in structures with very high aspect ratios is known as Atomic Layer Deposition (the ALD or ALCVD method). In particular, these dielectrics can therefore be combined very well with methods for increasing the surface area, for example wet bottle, roughening the surface in the trench etc.

The procedure according to the invention as claimed in claim 3 or 5 or else 15 or 17 has the advantage over the known approaches to a solution that the parasitic capacitance of the space-charge region can be eliminated by the use of metal electrodes.

According to a preferred development, the first capacitor plate is a region of increased doping in the semiconductor substrate in the lower region of the trench, and the second capacitor plate is the conducting filling material.

According to a further preferred development, a second metal electrode layer is provided in the upper region of the trench and is in electrical connection with the first metal electrode layer.

According to a further preferred development, a second metal electrode layer is provided in the upper region of the trench and is in electrical connection with the fourth metal electrode layer.

According to a further preferred development, the dielectric layer and the fourth metal electrode layer are led into the region of the isolation collar.

According to a further preferred development, the third metal electrode layer is led into the region of the isolation collar.

According to a further preferred development, the first and/or second and/or third and/or fourth metal electrode layer and/or the dielectric layer are applied by an ALD or ALCVD method and/or a CVD method.

According to a further preferred development, the first and/or second and/or third and/or fourth metal electrode layer has at least one of the following materials: TiN, WN, TaN, HfN, ZrN, Ti, W, Ta, Si, TaSiN, WSiN, TiAlN, WSi, MoSi, CoSi or similar materials.

According to a further preferred development, the trench has a lower widened region.

According to a further preferred development, the dielectric layer has at least one of the following materials: Al₂O₃, Ta₂O₅, ZrO₂, HfO₂, Y₂O₃, La₂O₃, TiO₂; Al—Ta—O, Al—Zr—O, Al—Hf—O, Al—La—O, Al—Ti—O, Zr—Y—O, Zr—Si—O, Hf—Si—O, Si—O—N, Ta—O—N, Gd₂O₃, SnO₃, La—Si—O, Ti—Si—O, LaAlO₃, ZrTiO₄, (Zr, Sn)TiO₄, SrZrO₄, LaAlO₄, BaZrO₃ or similar materials.

According to a further preferred development, the conducting filling material is composed of a first conducting filling layer in the lower trench region and a second conducting filling layer in the upper trench region.

Exemplary embodiments of the present invention are represented in the drawings and are explained in more detail in the following description.

In the figures:

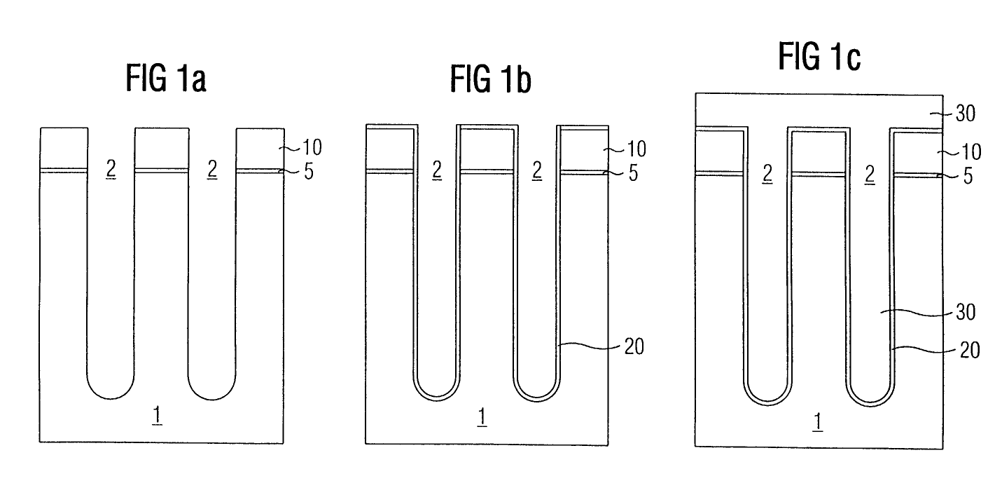

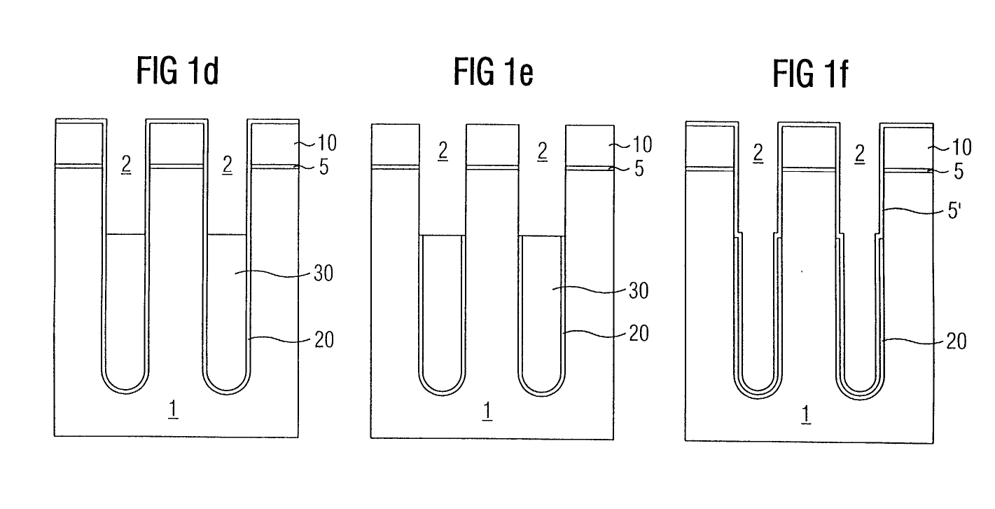

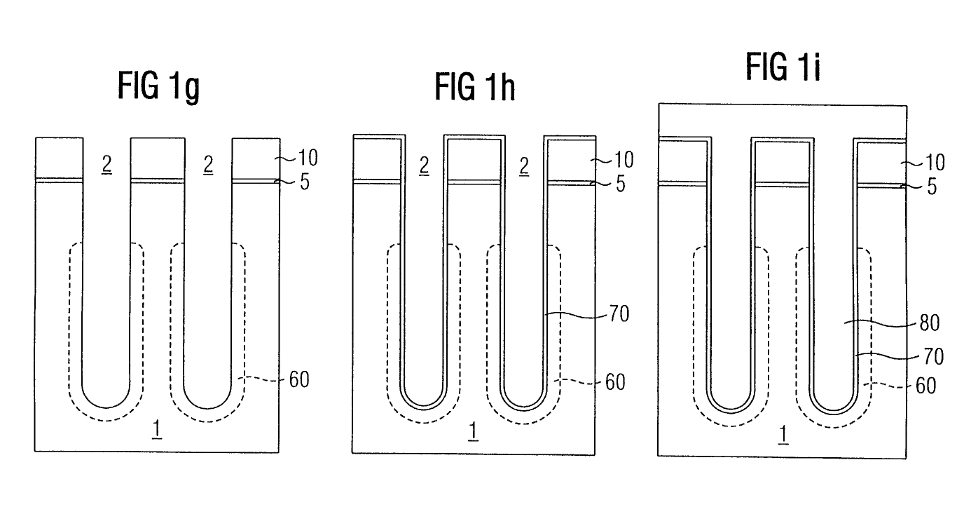

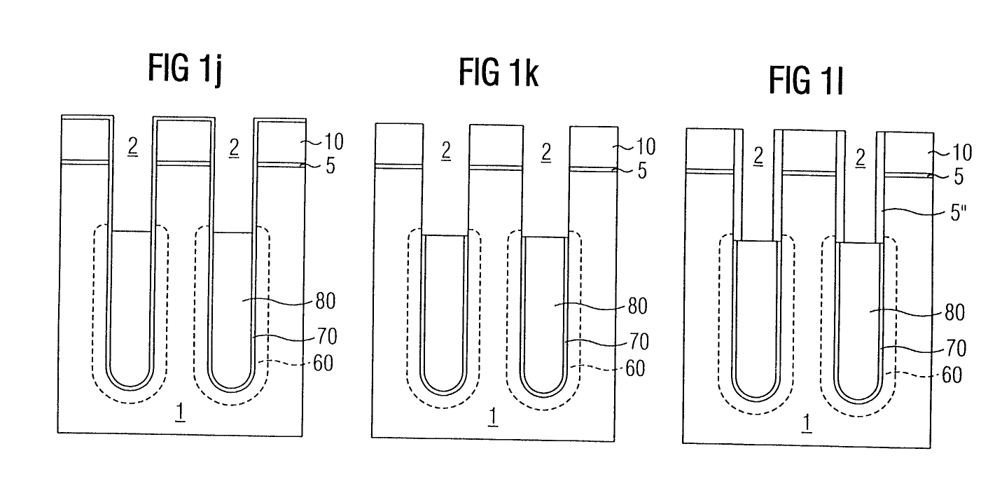

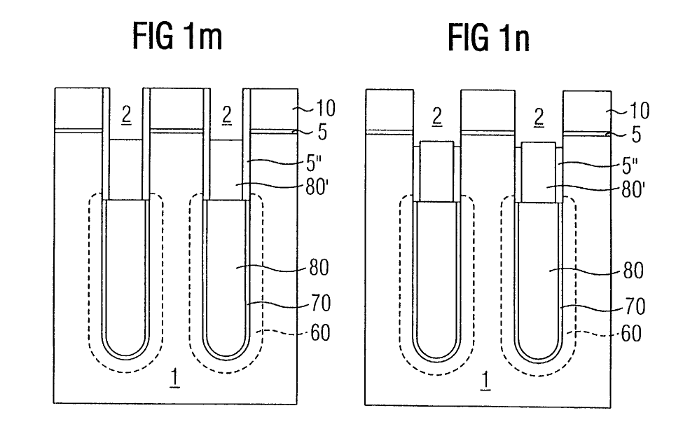

FIGS. 1a-n show the method steps for producing a first exemplary embodiment of the trench capacitor according to the invention that are essential for understanding the invention;

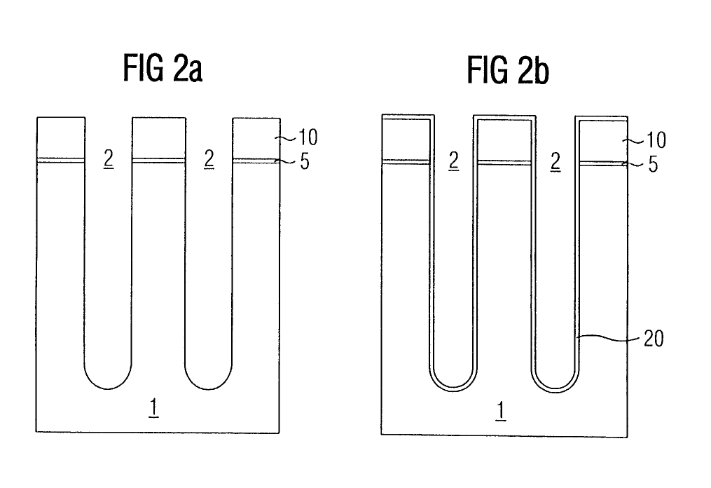

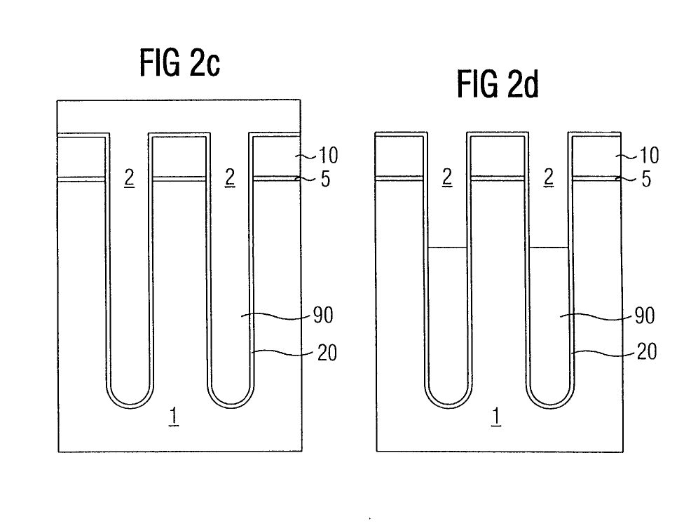

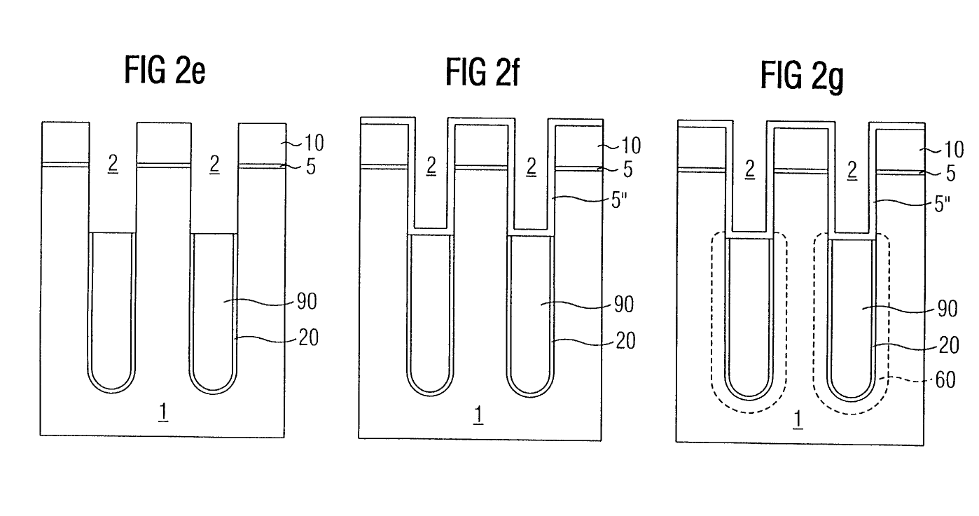

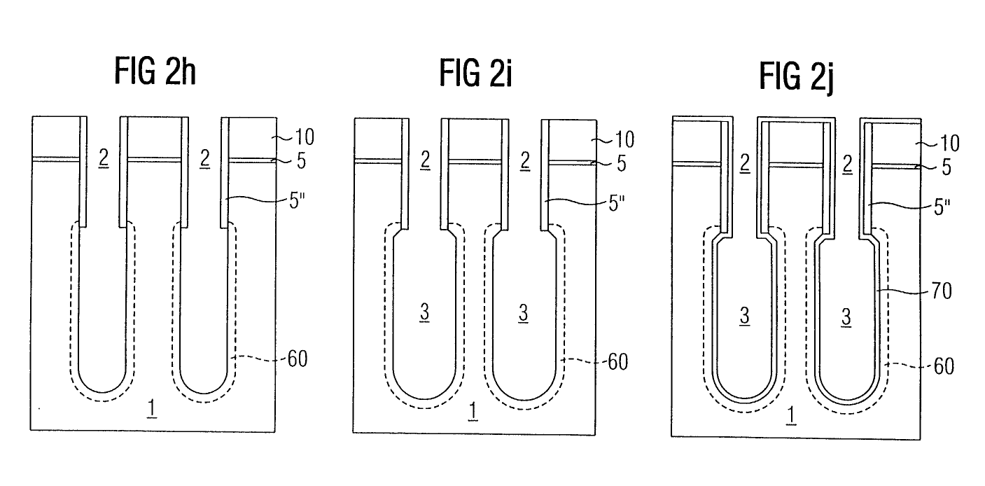

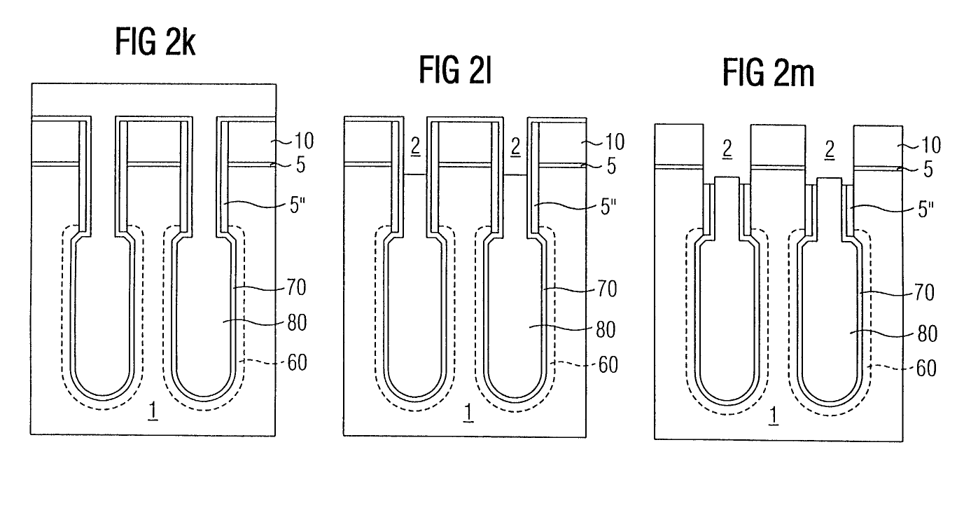

FIGS. 2a-m show the method steps for producing a second exemplary embodiment of the trench capacitor according to the invention that are essential for understanding the invention;

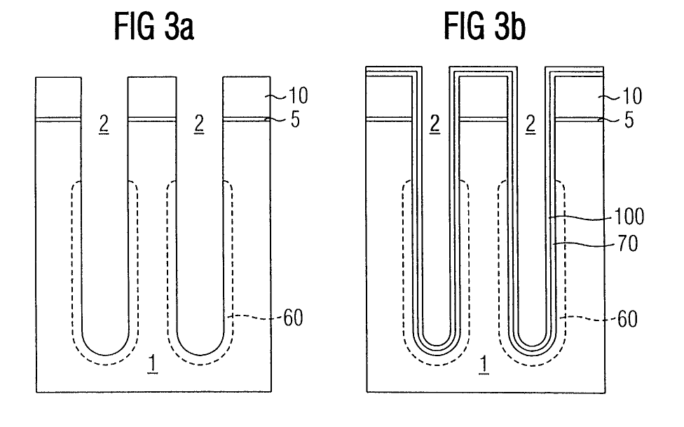

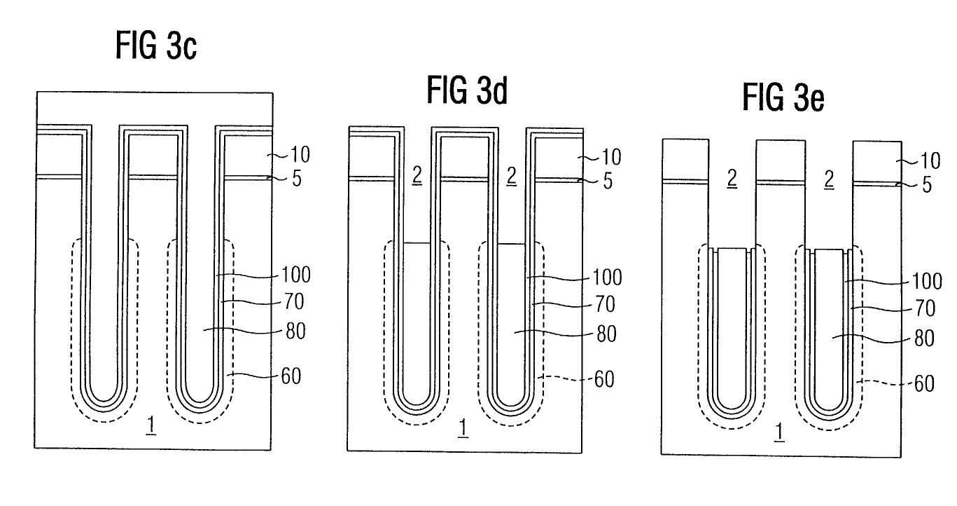

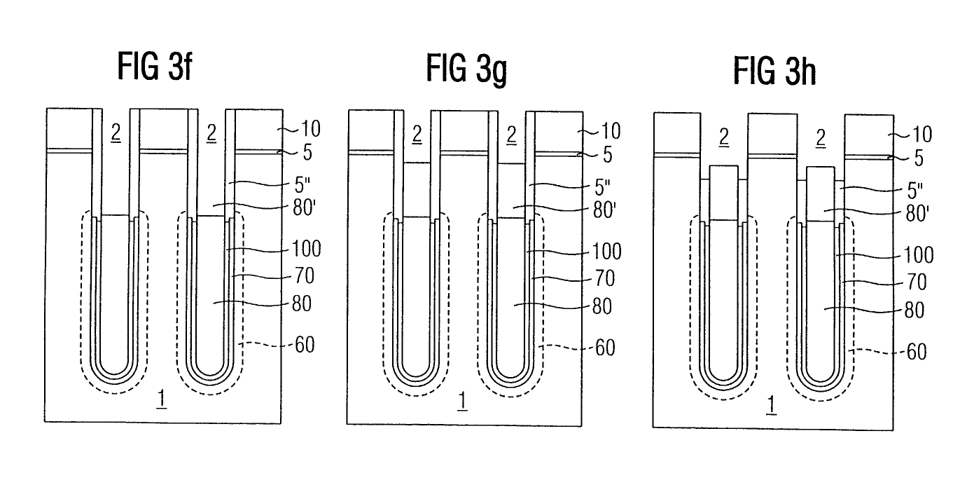

FIGS. 3a-h show the method steps for producing a third exemplary embodiment of the trench capacitor according to the invention that are essential for understanding the invention;

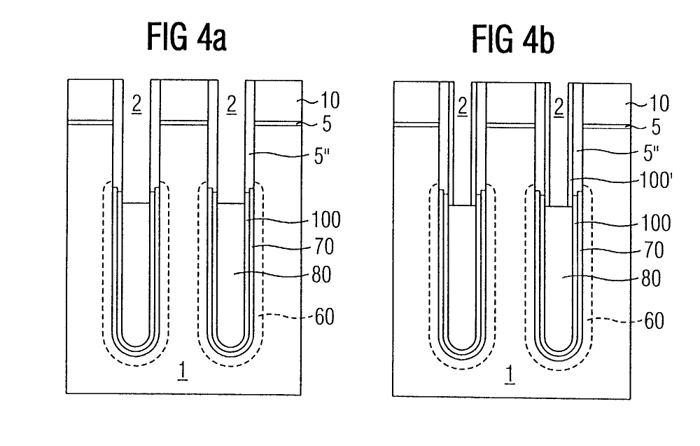

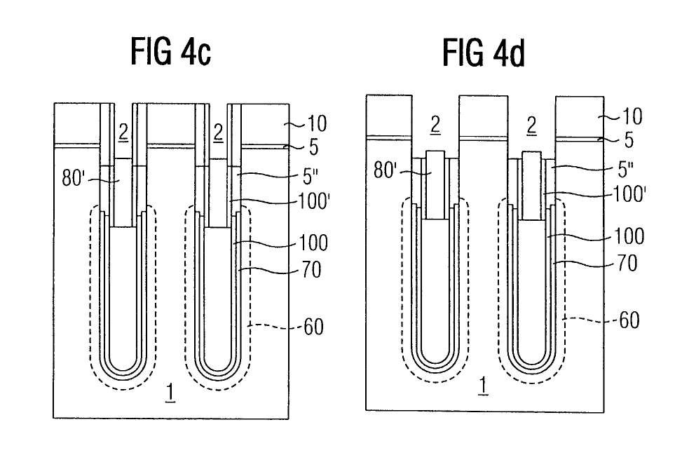

FIGS. 4a-d show the method steps for producing a fourth exemplary embodiment of the trench capacitor according to the invention that are essential for understanding the invention;

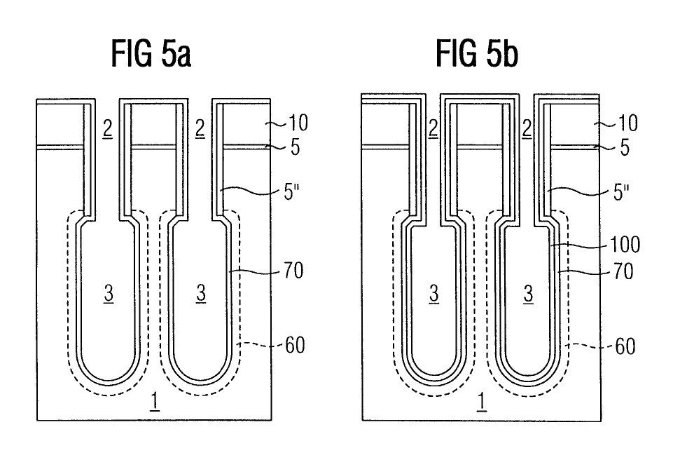

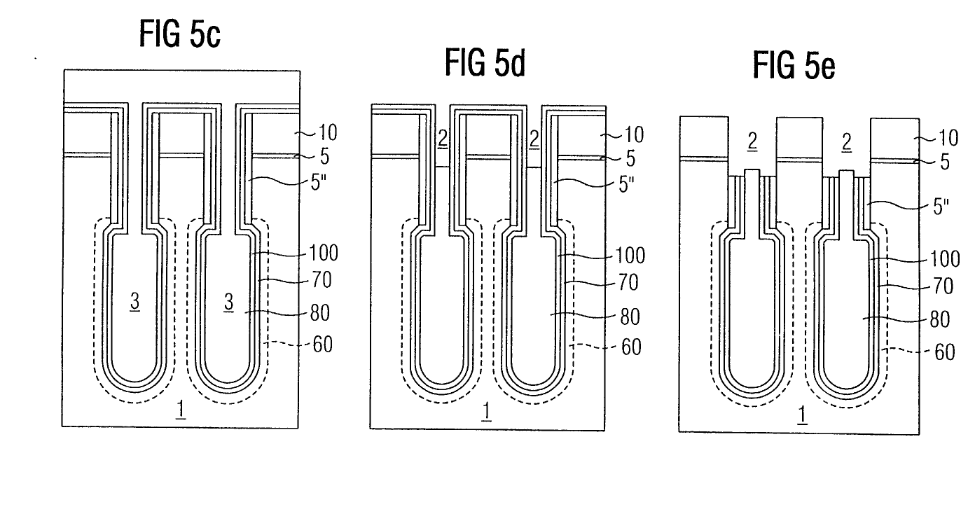

FIGS. 5a-e show the method steps for producing a fifth exemplary embodiment of the trench capacitor according to the invention that are essential for understanding the invention;

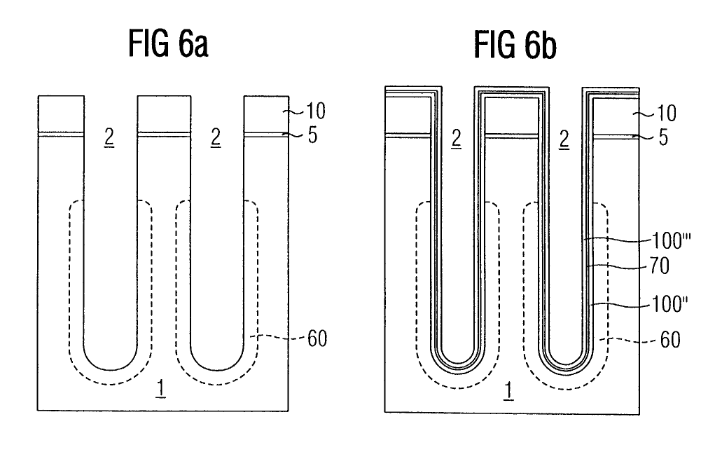

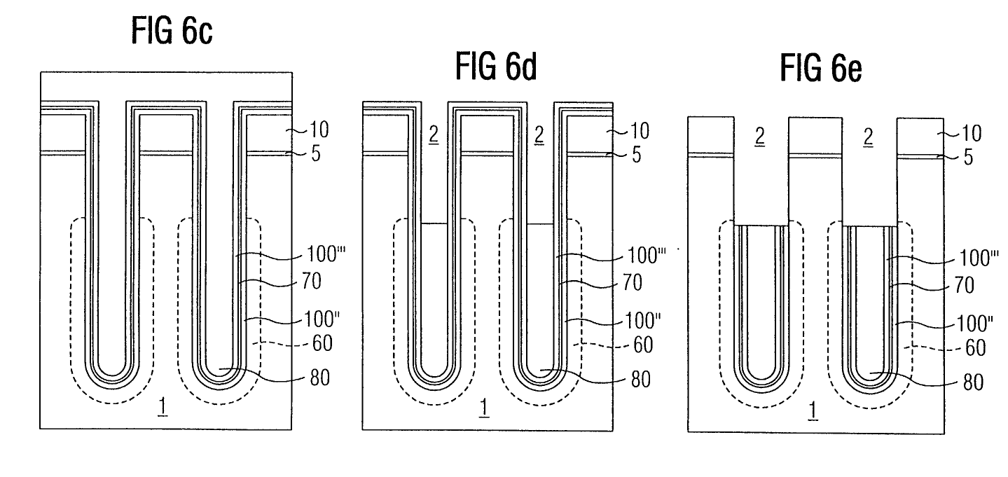

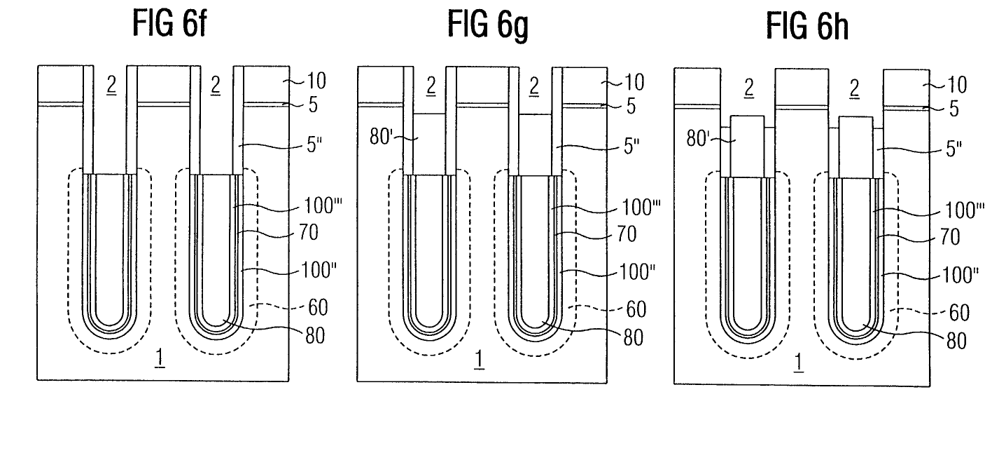

FIGS. 6a-h show the method steps for producing a sixth exemplary embodiment of the trench capacitor according to the invention that are essential for understanding the invention;

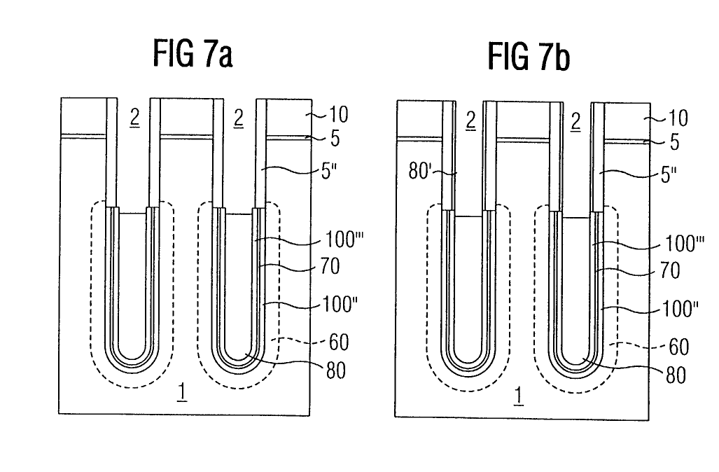

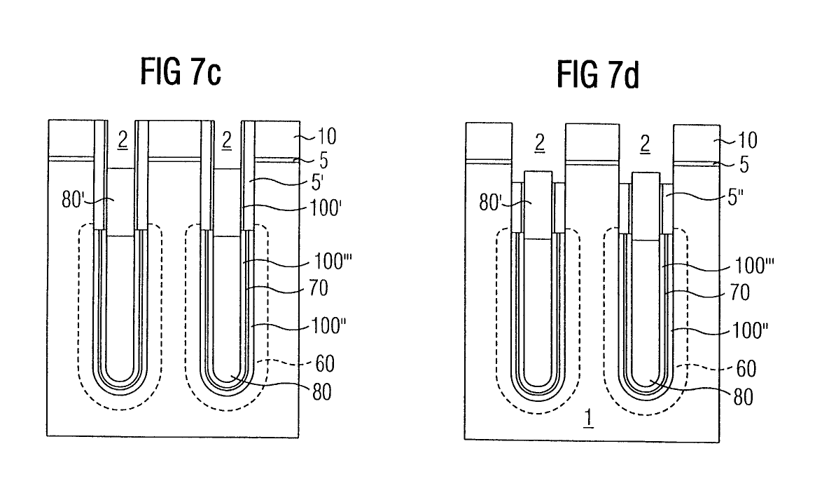

FIGS. 7a-d show the method steps for producing a seventh exemplary embodiment of the trench capacitor according to the invention that are essential for understanding the invention;

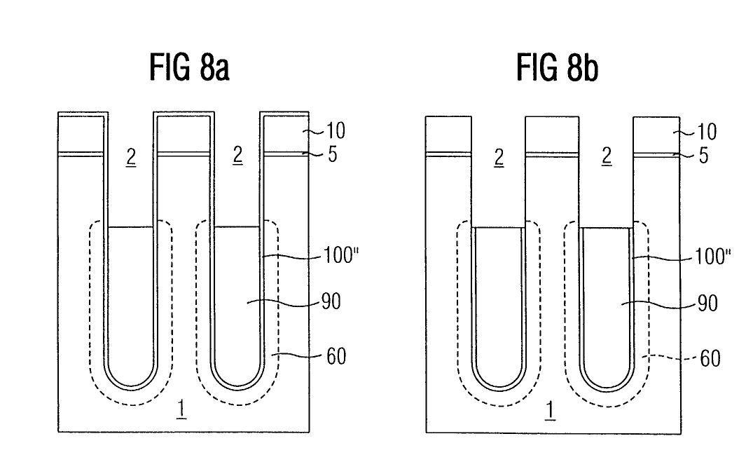

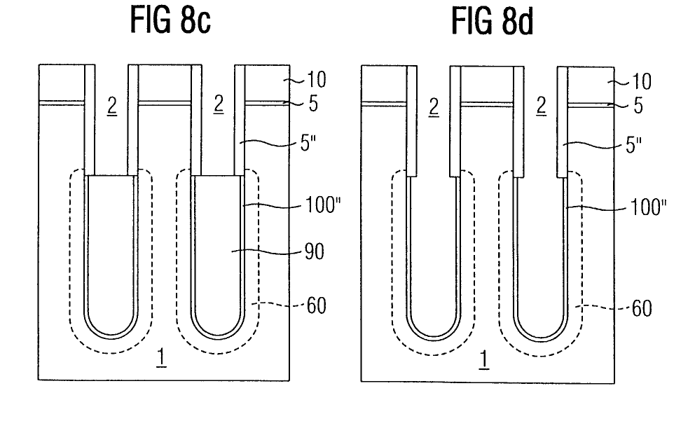

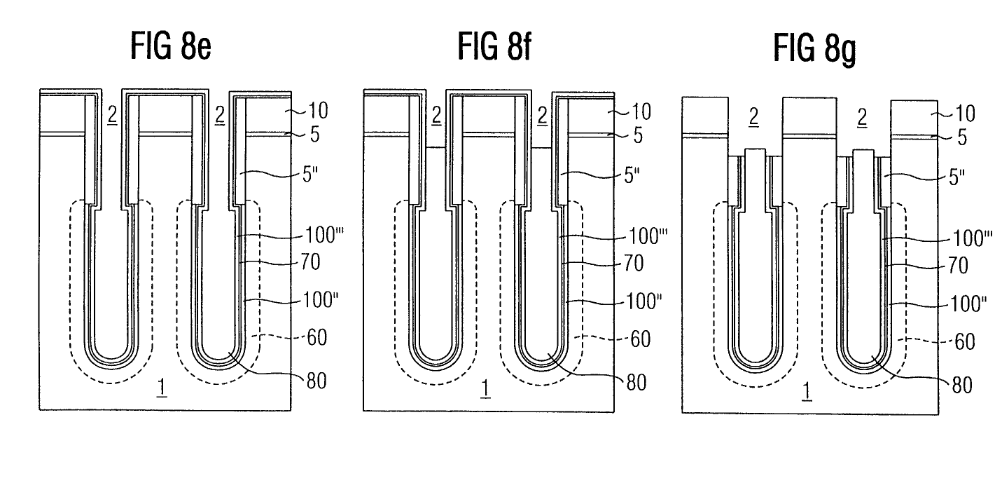

FIGS. 8a-g show the method steps for producing an eighth exemplary embodiment of the trench capacitor according to the invention that are essential for understanding the invention;

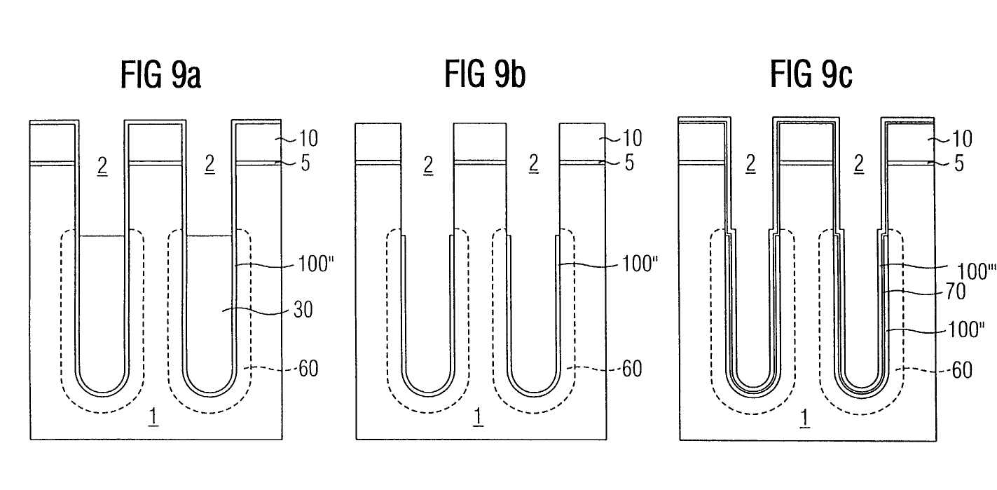

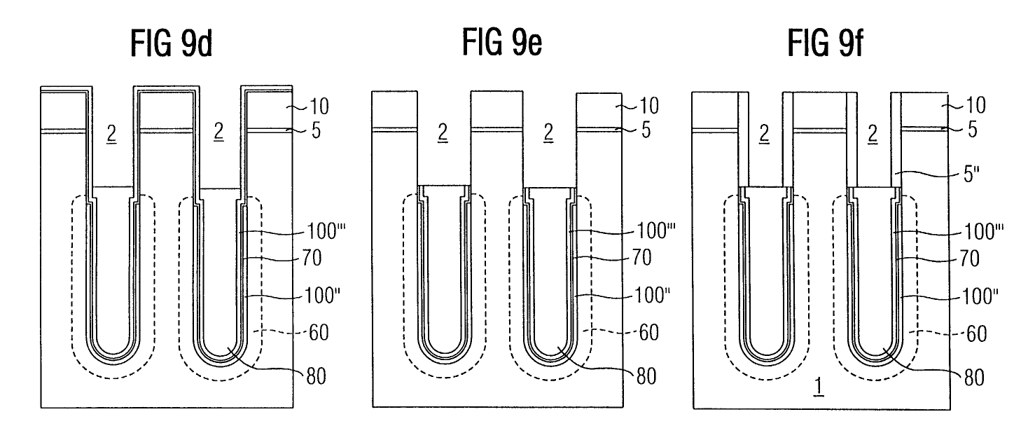

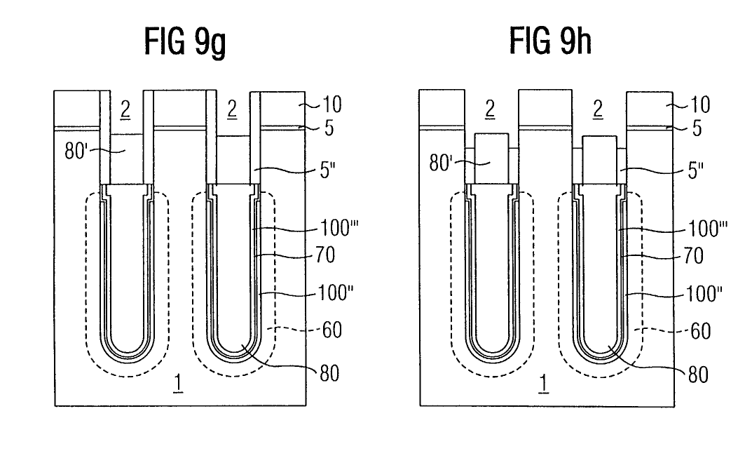

FIGS. 9a-h show the method steps for producing a ninth exemplary embodiment of the trench capacitor according to the invention that are essential for understanding the invention;

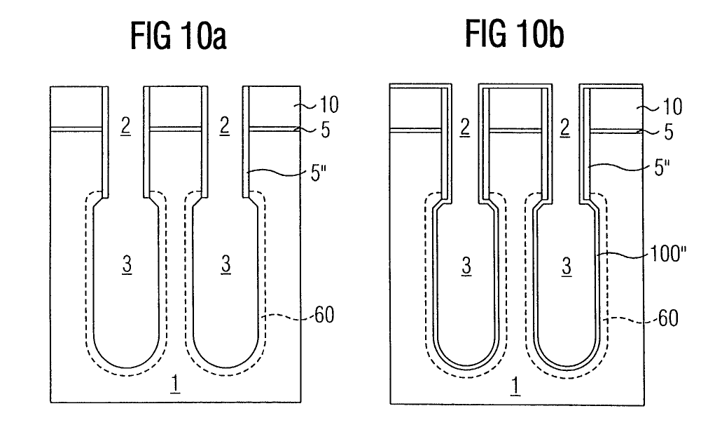

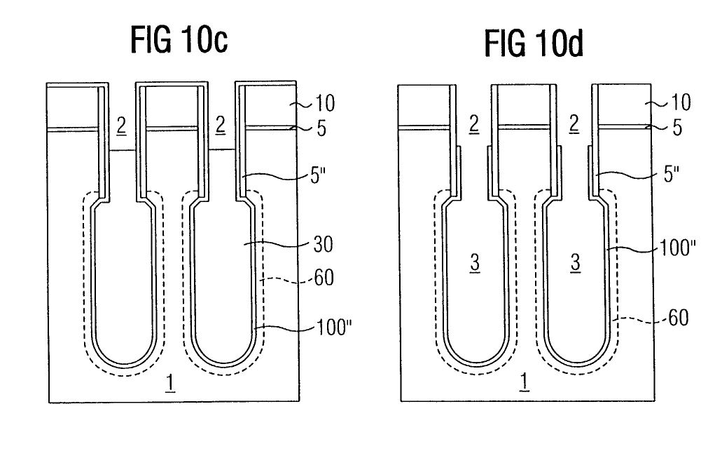

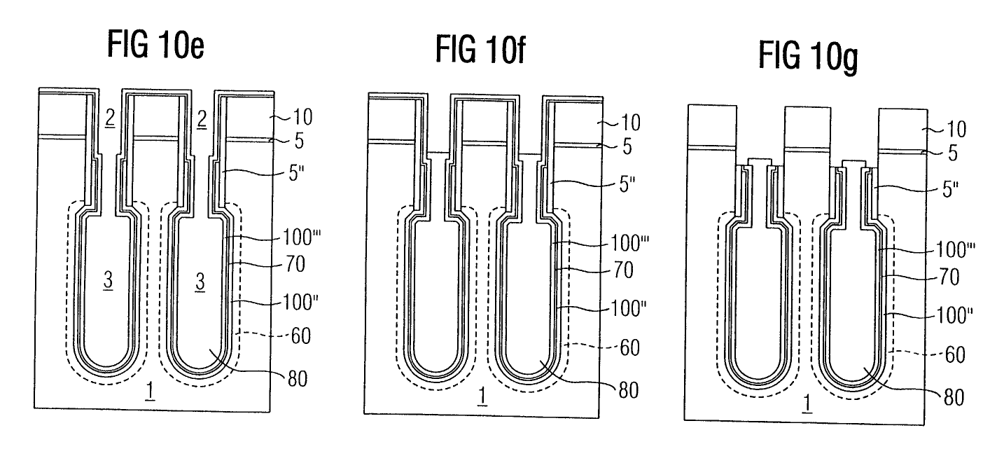

FIGS. 10a-g show the method steps for producing a tenth exemplary embodiment of the trench capacitor according to the invention that are essential for understanding the invention.

In the figures, the same designations denote identical or functionally identical components.

FIGS. 1a-n show the method steps for producing a first exemplary embodiment of the trench capacitor according to the invention that are essential for understanding the invention.

In the present first embodiment, a pad oxide layer 5 and a pad nitride layer 10 are firstly deposited on a silicon substrate 1, as shown in FIG. 1a. Then, a further pad oxide layer (not represented) is deposited and these layers are then structured by means of a photoresist mask (likewise not shown) and a corresponding etching process to form what is known as a hard mask. Using this hard mask, trenches 2 with a typical depth of approximately 1-10 μm are etched into the silicon substrate 1. After that, the uppermost pad oxide layer is removed, to reach the state represented in FIG. 1a.

In a following process step, arsenic silicate glass (ASG) 20 is deposited on the resultant structure, as shown in FIG. 1b, so that the ASG 20 in particular completely lines the trenches 2.

In a further process step, as shown in FIG. 1c, filling of the resultant structure with photoresist 30 takes place. According to FIG. 1d, this is followed by a resist recessing, or removal of resist, in the upper region of the trenches 2. This expediently takes place by isotropic dry-chemical etching.

In a further process step according to FIG. 1e, a likewise isotropic etching of the ASG 20 takes place in the unmasked, resist-free region, to be precise preferably in a wet-chemical etching process. After that, the resist 30 is removed in a plasma-assisted and/or wet-chemical process.

As shown in FIG. if, after that a covering oxide 5′ is deposited on the resultant structure.

In a further process step according to FIG. 1g, an outdiffusion of the arsenic from the ASG 20 still remaining into the surrounding silicon substrate 1 takes place in a heat-treatment step to form the buried plate 60, which forms a first capacitor electrode. Following this, the covering oxide 5′ and the remaining ASG 20 are expediently removed wet-chemically.

According to FIG. 1h, a special dielectric 70 with a high dielectric constant is then deposited onto the resultant structure by means of the ALD or ALCVD method (Atomic Layer Deposition). Alternatively, the deposition may take place by Atomic Layer Chemical Vapor Deposition (ALCVD) or other suitable CVD methods. The following come into consideration in particular as materials for the dielectric 60 with a high dielectric constant: Al₂O₃, Ta₂O₅, ZrO₂, HfO₂, Y₂O₃, La₂O₃, TiO₂; Al—Ta—O, Al—Zr—O, Al—Hf—O, Al—La—O, Al—Ti—O, Zr—Y—O, Zr—Si—C, Hf—Si—C, Si—O—N, Ta—C—N and similar materials. This deposition can be carried out with very good uniformity and conformality on account of the ALD or ALCVD or CVD method.

In a further process step, according to FIG. 1i, arsenic-doped polycrystalline silicon 80 is deposited on the resultant structure as the second capacitor plate, so that the trenches 2 are completely filled. Alternatively, polysilicon-germanium can also be used for the filling.

In a subsequent process step according to FIG. 1j, the doped polysilicon 80, or the polysilicon-germanium, is etched back to the upper side of the buried plate 60.

To achieve the state represented in FIG. 1k, an isotropic etching of the dielectric 70 with a high dielectric constant then takes place in the upper exposed region of the trenches 2, to be precise either by a wet-chemical etching process or by a dry-chemical etching process.

In a subsequent process step according to FIG. 11, a collar oxide 5″ is formed in the upper region of the trenches 2. This takes place by an oxide deposition over the full surface area and subsequent anisotropic etching of the oxide, so that the collar oxide 5″ remains on the side walls in the upper trench region.

As illustrated in FIG. 1m, in a subsequent process step polysilicon 80′ doped with arsenic is again deposited and etched back.

According to FIG. 1n, finally there follows a wet-chemical removal of the collar oxide 5″ in the upper trench region.

This essentially completes the forming of the trench capacitor. The forming of the capacitor connections and their production and connection with the associated selection transistor are well-known in the prior art and need not be mentioned any further to explain the present invention.

FIGS. 2a-m show the method steps for producing a second exemplary embodiment of the trench capacitor according to the invention that are essential for understanding the invention.

In the first embodiment above, the collar was formed after depositing the dielectric 70 with a high dielectric constant. In the second embodiment, now described, the forming of the collar takes place before the depositing of the dielectric 70 with a high dielectric constant.

In particular, the process steps according to FIGS. 2a and 2b correspond to the process steps already explained with reference to FIGS. 1a and 1b.

As represented in FIG. 2c, the depositing of the ASG layer 20 is followed by filling of the resultant structure with undoped polycrystalline silicon 90, which is then removed by isotropic dry-chemical etching in the upper region of the trench to achieve the state shown in FIG. 2d.

In a further process step, the ASG 20 is removed in the upper exposed trench region by a wet-chemical isotropic etching step, as shown in FIG. 2e. The depositing of the collar oxide 5′ over the full surface area, as shown in FIG. 2f, follows.

In the next process step according to FIG. 2c, arsenic is diffused out of the ASG 20 into the surrounding region of the silicon substrate 1, to form the buried plate 60.

An anisotropic etching of the collar oxide 5″ follows, to remove the latter from the surface of the resultant structure, so that it only remains on the side walls in the upper region of the trenches 2. After that, the polysilicon 90 is removed by isotropic etching, and in a further step the ASG 20 is likewise removed by an isotropic wet-chemical etching process. This leads to the state shown in FIG. 2h.

In a further process step, the forming of a widened lower trench region 3 then takes place by an etching process known in the prior art, or a wet-bottle etching process, which leads to the structure shown in FIG. 2i.

In the next process step according to FIG. 2j, the depositing of the dielectric 70 with a high dielectric constant takes place by means of the ALD or ALCVD method or CVD method already mentioned in connection with the first embodiment. The materials with a high dielectric constant that are particularly suitable for this purpose have likewise already been mentioned in connection with the first embodiment.

As can be seen from FIG. 2j, the coverage of the structure with the dielectric 70 with a high dielectric constant is very uniform on account of the special nature of the depositing method used, which ensures that no unwanted leakage currents occur at critical points, such as for example edges or pronounced curvatures.

In the next process step, a depositing of arsenic-doped polysilicon 80 or polysilicon-germanium takes place, which leads to the structure shown in FIG. 2k.

By etching back the polysilicon or polysilicon-germanium, the structure represented in FIG. 21 is obtained.

Finally, a wet-chemical isotropic etching of the dielectric 70 with a high dielectric constant and of the collar oxide 5″ takes place in the upper region of the trenches 2, to obtain the structure represented in FIG. 2m.

FIGS. 3a-h show the method steps for producing a third exemplary embodiment of the trench capacitor according to the invention that are essential for understanding the invention.

In this third embodiment of the invention, the state shown in FIG. 3a corresponds to the state shown in FIG. 1g, the pre-history of which has already been explained in detail.

According to FIG. 3b, the special dielectric 70 with a high dielectric constant is then deposited onto the resultant structure by means of the ALD or ALCVD method, as explained in detail in connection with FIG. 1h.

As a difference from the first embodiment, this is followed by the depositing of a metal electrode film 100 by means of the ALD or ALCVD method or some other suitable CVD method.

The following come into consideration in particular as materials for the metal electrode 100: TiN, WN, TaN, HfN, ZrN, Ti, W, Ta, Si, TaSiN, WSiN, TiAlN, WSi, MoSi, CoSi and metal-silicon nitrides in general or similar materials.

In a further process step, arsenic-doped polycrystalline silicon 80 is deposited on the resultant structure according to FIG. 3c, so that the trenches 2 are completely filled. Alternatively, polysilicon-germanium can also be used for the filling.

In a subsequent process step according to FIG. 3d, the doped polysilicon 80 or the polysilicon-germanium is etched back to the upper side of the buried plate 60.

To achieve the state represented in FIG. 3e, an isotropic etching of the dielectric 70 with a high dielectric constant and of the metal electrode 100 then takes place in the upper exposed region of the trenches 2, to be precise either by a wet-chemical etching process and/or by a dry-chemical etching process.

In a subsequent process step according to FIG. 3f, a collar oxide 5″ is formed in the upper region of the trenches 2. This takes place by an oxide deposition over the full surface area and a subsequent anisotropic etching of the oxide, so that the collar oxide 511 remains on the side walls in the upper trench region.

As illustrated in FIG. 3g, in a subsequent process step polysilicon 80′ doped with arsenic is again deposited and etched back.

According to FIG. 3h, finally there follows a wet-chemical removal of the collar oxide 5″ in the upper trench region.

FIGS. 4a-d show the method steps for producing a fourth exemplary embodiment of the trench capacitor according to the invention that are essential for understanding the invention.

The state represented in FIG. 4a corresponds to the state according to FIG. 3f, the pre-history of which was explained in detail in connection with the third embodiment above, although a further recessing of the polysilicon 80 was carried out in a dry-chemical manner directly after the state of FIG. 3f to partially expose the metal electrode 100.

According to FIG. 4b, in a way analogous to the metal electrode film 100, after that a further metal electrode film 100′ is deposited and anisotropically etched back, so that it remains in the upper region of the trenches 2. Alternatively, it is also possible to dispense with the anisotropic etching-back or else for the upper trench region to be completely filled with metal (i.e. without polysilicon 80′).

A depositing of arsenic-doped polysilicon 80′ and corresponding etching-back follows, to achieve the state represented in FIG. 4c.

Finally, according to FIG. 4d, the metal electrode film 100′ and the collar oxide 5″ are etched back, expediently wet-chemically, in the upper region of the trenches 2.

FIGS. 5a-e show the method steps for producing a fifth exemplary embodiment of the trench capacitor according to the invention that are essential for understanding the invention.

The state represented in FIG. 5a corresponds to the state represented in FIG. 2j, the pre-history of which was explained above in detail in connection with the second embodiment.

According to FIG. 5b, subsequently the metal electrode film 100 is deposited on the resultant structure by means of the ALD or ALCVD method or the CVD method, to be precise in a way analogous to that explained in connection with FIG. 3b.

In the next process step, a depositing of arsenic-doped polysilicon 80 or polysilicon-germanium takes place, which leads to the structure shown in FIG. Sc. By etching back the polysilicon or polysilicon-germanium, the structure represented in FIG. 5d is obtained.

Finally, a wet-chemical isotropic etching of the metal electrode film 100, of the dielectric 70 with a high dielectric constant and of the collar electrode 5′ takes place in the upper region of the trenches 2, to obtain the structure represented in FIG. 5e.

FIGS. 6a-h show the method steps for producing a sixth exemplary embodiment of the trench capacitor according to the invention that are essential for understanding the invention.

The structure represented in FIG. 6a corresponds to the structure represented in FIG. 1g, the pre-history of which has already been explained in detail in connection with the first embodiment.

According to FIG. 6b, this is followed by the depositing of a metal-isolator-metal structure, comprising the metal electrode layer 100″, the dielectric layer 70 and the metal electrode layer 100′″. The depositing methods and the materials used for these layers correspond to those of the first and third embodiments explained above, and they are therefore not described again here.

In a further process step, arsenic-doped polycrystalline silicon 80 is deposited on the resultant structure according to FIG. 6c, so that it completely fills the trenches 2. Alternatively, polysilicon-germanium can also be used for the filling.

In a subsequent process step according to FIG. 6d, the doped polysilicon 80, or the polysilicon-germanium, is etched back to the upper side of the buried plate 60.

To achieve the state represented in FIG. 6e, an isotropic etching of the metal electrode layers 100″ and 100′″ and of the dielectric 70 with a high dielectric constant then takes place in the upper exposed region of the trenches 2, to be precise either by a wet-chemical etching process or by a dry-chemical etching process.

In a subsequent process step according to FIG. 6f, a collar oxide 5″ is formed in the upper region of the trenches 2. This takes place by an oxide deposition over the full surface area and subsequent anisotropic etching of the oxide, so that the collar oxide 5″ remains on the side walls in the upper trench region.

As illustrated in FIG. 6g, in a subsequent process step polysilicon 80′ doped with arsenic is again deposited and etched back.

According to FIG. 6h, finally there follows a wet-chemical removal of the collar oxide 5″ in the upper trench region.

FIGS. 7a-d show the method steps for producing a seventh exemplary embodiment of the trench capacitor according to the invention that are essential for understanding the invention.

The state represented in FIG. 7a corresponds to the state represented in FIG. 6f, a further recessing having been carried out on the polysilicon 80, so that the metal electrode layer 100′″ is partially exposed in the trench 2.

According to FIG. 7b, in a subsequent process step the further metal electrode layer 100′ is deposited and anisotropically etched, so that the metal electrode layer 100′ lines the inside walls in the upper region of the trench 2. Alternatively, it is also possible to dispense with the anisotropic etching back or else to fill the upper trench region entirely with metal (i.e. without polysilicon 80′).

In the next process step, a depositing of arsenic-doped polysilicon 80′ or polysilicon-germanium takes place. By etching back the polysilicon or polysilicon-GR germanium, the structure represented in FIG. 7c is obtained.

Finally, a wet-chemical isotropic etching of the metal electrode film 100′ and of the collar electrode 5″ then takes place in the upper region of the trenches 2, to obtain the structure represented in FIG. 7d. FIGS. 5a-g show the method steps for producing an eighth exemplary embodiment of the trench capacitor according to the invention that are essential for understanding the invention.

The structure shown in FIG. 8a corresponds to the structure shown in FIG. 1g, a metal electrode film 100′ having been deposited on the structure according to FIG. 1g by the ALD or CVD method, as explained above. Furthermore, undoped polysilicon 90 has been deposited over the structure obtained in this way, and etched back to the upper side of the buried plate 60.

According to FIG. 8b, an etching back of the metal electrode film 100″ then takes place in the exposed region by a corresponding isotropic etching process.

According to FIG. 8c, the collar oxide 5″ is then deposited and anisotropically etched back, as already described above. Removal of the undoped polysilicon 90 in the lower trench region follows, which leads to the structure shown in FIG. 8d.

In a next process step, which is shown in FIG. 8e, a depositing of the special dielectric 70 with a high dielectric constant and of the further metal electrode layer 100′″ takes place.

On the resultant structure, polysilicon 80 doped with arsenic is deposited and etched back over the full surface area, as represented in FIG. 8f.

Finally, the metal electrode layer 100′″, the dielectric layer 70 and the collar oxide 5″ are etched back in the upper region, to obtain the structure shown in FIG. 8g.

This eighth embodiment allows the collar to be arranged in a self-adjusted manner in relation to the lower metal electrode 100″.

FIGS. 9a-h show the method steps for producing a ninth exemplary embodiment of the trench capacitor according to the invention that are essential for understanding the invention.

According to FIG. 9a, a depositing of the metal electrode layer 100′″ takes place onto the structure shown in FIG. 1g, onto which the photoresist 30 has been applied and etched back.

According to FIG. 9b, this is followed by an etching back of the metal electrode layer 100″ and removal of the photoresist 30 by a corresponding etching process.

As represented in FIG. 9c, the dielectric layer 70 with a high dielectric constant and the further metal electrode layer 100′″ are then deposited on the resultant structure.

As shown in FIG. 9d, arsenic-doped polysilicon 80 is deposited on the resultant structure and etched back to above the region of the buried plate 60.

In a subsequent isotropic etching step, the metal electrode layer 100′″ and the dielectric layer 70 are likewise etched back, to obtain the structure shown in FIG. 9e.

In a subsequent process step according to FIG. 9f, a collar oxide 5′″ is formed in the upper region of the trenches 2. This takes place by a depositing of oxide over the full surface area and subsequent anisotropic etching of the oxide, so that the collar oxide 5″ remains on the side walls in the upper trench region.

As illustrated in FIG. 9g, in a subsequent process step polysilicon 80′ doped with arsenic is again deposited and etched back.

According to FIG. 9h, finally there follows a wet-chemical removal of the collar oxide 5″ in the upper trench region.

In the ninth embodiment, illustrated in FIGS. 9a to h, the collar is applied in a self-adjusted manner in relation to the dielectric 70 and in relation to the upper electrode 100″.

FIGS. 10a-g show the method steps for producing a tenth exemplary embodiment of the trench capacitor according to the invention that are essential for understanding the invention.

The state shown in FIG. 10a corresponds to the state according to FIG. 2i, the pre-history of which has already been explained in detail in connection with the above second embodiment.

To achieve the state shown in FIG. 10b, the metal electrode layer 100″ is deposited on the resultant structure.

There follows a filling of the structure with photoresist 30 and etching back of the photoresist 30, to reach the structure shown in FIG. 10c. This is followed by an etching back of the metal electrode layer 100″ in the exposed region and then removal of the photoresist 30. This is represented in FIG. 10d. Subsequently, the special dielectric 70 with a high dielectric constant and also the further metal electrode layer 100′″αare deposited on the resultant structure.

There follows a depositing and etching-back of arsenic-doped polysilicon 80 or polysilicon-germanium. This leads to the structure shown in FIG. 10f.

Finally, the two metal electrode layers 100′″ and 100 the dielectric layer 70 and the collar oxide 5′ are etched back in the upper region, to obtain the structure shown in FIG. 10g.

Although the present invention was described above on the basis of a preferred exemplary embodiment, it is not restricted to this but can be modified in various ways.

In particular, the cited materials are given only by way of example and can be replaced by other materials with suitable properties. The same applies to the etching processes and depositing processes named.

The present disclosure relates to subject matter contained in priority German Patent Application No. 100 34.003.2, filed on Jul. 7, 2000, the contents of which is herein expressly incorporated by reference in its entirety.

What is claimed is:

1. A trench capacitor for use in a semiconductor memory cell, the capacitor comprising:
a trench formed in a semiconductor substrate;
a first and second conducting capacitor plate each located in said trench;
a dielectric layer located between said first and second capacitor plates, as a capacitor dielectric;
an isolation collar in an upper region of said trench; and
an optional conducting filling material, filled into the trench;
wherein said dielectric layer has been applied by one of an ALD, ALCVD, and CVD method.

2. The trench capacitor as claimed in claim 1, wherein said first capacitor plate is a region of increased doping in the semiconductor substrate in a lower region of said trench and said second capacitor plate is said conducting filling material.

3. A trench capacitor for use in a semiconductor memory cell, the trench capacitor comprising:
a trench formed in a semiconductor substrate;
a first and a second conducting capacitor plate, located in said trench;
a dielectric layer, located between said first and said second capacitor plates, as the capacitor dielectric;
an isolation collar in an upper region of the trench; and
an optional conducting filling material in said trench;
wherein:
said first capacitor plate is a region of increased doping in the semiconductor substrate in a lower region of the trench; and
a first metal electrode layer is provided on said dielectric layer inside said trench as said second capacitor plate.

4. The trench capacitor as claimed in claim 3, wherein a second metal electrode layer is provided in the upper region of said trench and is in electrical connection with said first metal electrode layer, and said second metal electrode layer optionally fills the upper trench region.

5. A trench capacitor for use in a semiconductor memory cell, the capacitor comprising:
a trench formed in a semiconductor substrate;
a first and a second conducting capacitor plate located in said trench;
a dielectric layer located between said first and said second capacitor plates, as a capacitor dielectric;
an isolation collar in an upper region of said trench; and
an optional conducting filling material, filled in said trench;
wherein:
a third metal electrode layer is provided between said dielectric layer and the semiconductor substrate as said first capacitor plate; and
a fourth metal electrode layer is provided on the other side of said dielectric layer as said second capacitor plate.

6. The trench capacitor as claimed in claim 5, wherein:
a second metal electrode layer is provided in the upper region of the trench and is in electrical connection with said fourth metal electrode layer; and
said second metal electrode layer optionally fills the upper trench region.

7. The trench capacitor as claimed in claim 5, wherein said dielectric layer and said fourth metal electrode layer are led into a region of said isolation collar.

8. The trench capacitor as claimed in claim 7, wherein said third metal electrode layer is led into the region of said isolation collar.

9. The trench capacitor as claimed in claim 3, wherein one of said first metal electrode layer, second metal electrode layer, third metal electrode layer, fourth metal electrode layer and said dielectric layer have been applied by one of an ALD, ALCVD and CVD methods.

10. The trench capacitor as claimed in claim 3, wherein one of said first, second third and fourth metal electrode layers comprises at least one of the following materials: TiN, WN, TaN, HfN, ZrN, Ti, W, Ta, Si, TaSiN, WSiN, TiAlN, WSi, MoSi and CoSi.

11. The trench capacitor as claimed in claim 1, wherein said trench has a lower widened region.

12. The trench capacitor as claimed in claim 1, wherein said dielectric layer comprises at least one of the following materials:
Al₂O₃, Ta₂O₅, ZrO₂, HfO₂, Y₂O₃, La₂O₃, TiO₂; Al—Ta—O, Al—Zr—O, Al—Hf—O, Al—La—O, Al—Ti—O, Zr—Y—O, Zr—Si—O, Hf—Si—O, Si—O—N, Ta—O—N, Gd₂O₃, SNO, La—Si—O, Ti—Si—O, LaAlO₃, ZrTiO₄, (Zr, Sn)TiO₄, SrZrO₄, LaAlO₄ and BaZrO₃.

13. The trench capacitor as claimed in claim 1, wherein said conducting filling material is composed of a first conducting filling layer in a lower trench region and a second conducting filling layer in the upper trench region.

14. A method for producing a trench capacitor, for use in a semiconductor memory cell, the method comprising:
forming a trench in a semiconductor substrate;
providing a first and a second conducting capacitor plate in the trench;
providing a dielectric layer as a capacitor dielectric between the first and the second capacitor plates;
forming an isolation collar in an upper region of the trench;
optionally filling a conducting filling material into the trench; and
applying the dielectric layer by one of an ALD, ALCVD and CVD method.

15. A method for producing a trench capacitor for use in a semiconductor memory cell, comprising:
forming a trench in a semiconductor substrate;
providing a first and a second conducting capacitor plate;
providing a dielectric layer as a capacitor dielectric between the first and the second capacitor plates;
forming an isolation collar in an upper region of the trench;
optionally filling the trench with a conducting filling material; and
providing a first metal electrode layer on the dielectric layer inside the trench as the second capacitor plate.

16. The method as claimed in claim 15, further comprising wherein a second metal electrode layer is provided in the upper region of the trench and is in electrical connection with the first metal electrode layer.

17. A method for producing a trench capacitor for use in a semiconductor memory cell, the method comprising:
forming a trench in a semiconductor substrate;
providing a first and a second conducting capacitor plate in the trench;
providing a dielectric layer as the capacitor dielectric, between the first and the second capacitor plates;
forming an isolation collar in an upper region of the trench;
optionally filling a conducting filling material into the trench;
providing a third metal electrode layer between the dielectric layer and the semiconductor substrate as the first capacitor plate; and
providing a fourth metal electrode layer on the other side of the dielectric layer as the second capacitor plate.

18. The method as claimed in claim 17, further comprising providing a second metal electrode layer between the isolation collar and the conducting filling material in the upper region of the trench, wherein the second metal electrode layer is in electrical connection with the fourth metal electrode layer.

19. The method as claimed in claim 17, further comprising leading the dielectric layer and the fourth metal electrode layer into a region of the isolation collar.

20. The method as claimed in claim 19, further comprising leading the third metal electrode layer into a region of the isolation collar.

21. The method as claimed in claim 16, further comprising applying one of the first metal electrode layer, second metal electrode layer, third metal electrode layer, fourth metal electrode layer and the dielectric layer, by one of an ALD, ALCVD, and CVD method.
